(19) United States
(12) Patent Application Publication
(10) Pub. No.: US 2007/0145344 A1
(43) Pub. Date: Jun. 28, 2007

(54) Resistance-change nanocrystal memory

(75) Inventor: Pei-Ren Jeng, Hsinchu Hsien (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/495,708

(22) Filed: Jul. 31, 2006

(30) Foreign Application Priority Data
Dec. 28, 2005 (TW) 094146931

(51) Int. Cl. H01L 29/02

(52) U.S. Cl. 257/2

(57) ABSTRACT

A resistance-change nanocrystal memory is proposed, which includes at least one memory unit. The memory unit further includes a channel and nanocrystals embedded in the channel. Electric charges in the nanocrystals are accessed, by applying a voltage to the channel. Then, conductivity of the channel is altered by the electric charges stored in the nanocrystals. Eventually, electric current is measured while an additional transistor is on, so as to achieve memory functions.

### FIELD OF THE INVENTION

The present invention is related to semiconductor memory devices, and more particularly, to a nanocrystal memory device for accessing electric charges.

### BACKGROUND OF THE INVENTION

Flash memory is a type of nonvolatile memory. In a flash memory, in addition to a typically formed insulating oxide layer, a floating gate is formed between the gate and channel of the metal oxide semiconductor (MOS) as in the traditional metal oxide semiconductor field-effect transistor (MOSFET). By altering the threshold voltage of a transistor or a memory unit in the flash memory, the channel can be opened or closed in order to achieve memory functions, and there is not any loss of data despite power interruption. In a typical flash memory, both the floating gate and the control gate are made of doped polysilicon. However, making a floating gate from polysilicon gives rise to a problem, that is, in the presence of a leakage pathway located anywhere in the tunnel oxide layer below the polysilicon floating gate, electric charges are unlikely to be stored in the polysilicon, and thus it is difficult to store data.

In an attempt to solve the problem, the use of a nanocrystal memory is then proposed. Unlike its predecessor whose floating gate is made of polysilicon, the proposed nanocrystal memory resorts to nanocrystals, rather than polysilicon, embedded between the gate layers. Electrical charges can be stored in the proposed nanocrystal memory, because the latter possesses the basic structure of a transistor plus the nanocrystals embedded between the gate layers. FIG. 1 is a cross-sectional view showing a conventional nanocrystal memory 100. The basic structure of a transistor, which comprises a substrate 101, a source 102, a drain 103, a gate oxide layer 104, and a gate electrode 105, coupled with the nanocrystals 106 embedded in a nanocrystal layer 107 interposed between the gate layers, enables the nanocrystal memory 100 to store electric charges.

Not only does the proposed nanocrystal memory overcome the drawbacks of the conventional way of making a floating gate from polysilicon, such as high operating voltage and low reading speed, to a great extent, but its retention time is longer than that of its predecessor's (where its predecessor has a floating gate made of polysilicon.)

However, as regards the fabrication of nanocrystals, the biggest technical problem nowadays lies in the control over the formation of nanocrystals. For example, where the nanocrystals in a nanocrystal layer are too small or excessively scattered, the nanocrystal layer fails to store sufficient electric charges, and in consequence the number of electric charges in the channel below the oxide layer decreases, which in turn leads to difficulty in reading. In other words, a low nanocrystals density or insufficient number of electric charges stored in a single nanocrystal may contribute to an insignificant difference between the threshold voltage of a nanocrystal layer which has been stored with electric charges and that of a nanocrystal layer which has not been stored with any electric charge; as a result, it is hard to discern whether electric charges have been stored in a nanocrystal layer, and thus reading is inefficient.

As regards the fabrication of nanocrystals, the top priority is to make as many nanocrystals as possible for storing sufficient electric charges, so as to increase the difference between the threshold voltage of a nanocrystal layer with stored electric charges and that of a nanocrystal layer without, and thereby enable the memory to read effectively. However, in the presence of a high nanocrystals density or an excess of electric charges stored in a single nanocrystal, the electric charges leap to neighboring nanocrystals readily, or, in another scenario, where the energy barrier is too small to stop the electric charges from escaping, the escaping electric charges tunnel into the oxide layer and therefore are not stored in the nanocrystals; as a result, electric charges are unlikely to be stored.

In addition, with the technology currently available, the typical way to downsize the nanocrystal memory is to make the tunnel oxide layer thin, which, however, is subject to the physical limit of direct tunneling and technical considerations. For this reason, the tunnel oxide layer can be thinned down but only to a limited extent.

Accordingly, the most urgent issue facing the industry now is devising another structure that can solve the problems arising from the existing memory fabrication technology. In other words, the new structure must be capable of enhancing electric charge retention as well as thinning down the tunnel oxide with a view to operating at low voltage.

### SUMMARY OF THE INVENTION

In light of the problems arising from the above prior art, the present invention provides a memory structure that is different from the traditional memory. The primary objective of the memory structure of the present invention is to improve a nanocrystal memory fabricated according to the prior art, wherein the prior art has its shortcomings, that is, nanocrystals configured to store electric charges are embedded between gate layers, but there is limited change in transistor threshold voltage because of a low nanocrystals density, and in consequence the memory cannot be read effectively and accurately.

Another objective of the present invention is to provide a method for directly embedding nanocrystals in a semiconductor channel, achieving memory functions by reading the value of resistance in the memory, and providing a channel not necessarily disposed above the silicon substrate so as to raise component density.

To achieve the above and other objectives, the present invention discloses a resistance-change nanocrystal memory device, which includes at least one memory unit and a reading component for reading an electric current passing through the memory unit. The memory unit includes a semiconductor material, a channel formed in the semiconductor material, and a plurality of nanocrystals located in the channel and configured to store electric charges, with a view to determining electrical properties of the channel and accessing the electric charges in the plurality of nanocrystals by voltage applied to the channel. The memory unit is connected to an additional transistor for reading the resistance of the memory unit. Each nanocrystal comprises an electrically conductive particle and an insulating layer which encloses the electrically conductive particle. Voltage is applied to the channel so as to access an electric charge stored in each nanocrystal. The electric charge stored in each nanocrystal can alter the resistance of the channel outside the nanocrystal. Electric current in the memory unit is read while the additional transistor is on, thereby achieving memory functions.

Unlike a conventional MOSFET wherein electric charges are stored in nanocrystals embedded between gate layers and then the difference in the threshold voltage of the channel disposed under the gate depends on whether electric charges are stored in the nanocrystals or not, the present invention proposes that, not only is the actual location of storage memory not limited to a nanocrystal electric charge storage layer interposed between the gate layers, but the channel is not necessarily disposed above the silicon substrate. Accordingly, the present invention overcomes the channel downsizing bottleneck of the prior art.

Unlike the prior art, the present invention allows sufficient number of electric charges to be stored in the nanocrystal storage layer disposed between the gate layers. By contrast, in the prior art, the oxidation layer has to be thinned down in order to hold more electric charges and maintain an operating voltage equivalent to, or even less than, the existing operating voltage, though at the cost of the other technical problems and retention deterioration. The prior art allows a memory to contain more electric charges by creating some insurmountable problems. The present invention solves the aforesaid problems.

### BRIEF DESCRIPTION OF THE DRAWINGS

The present invention can be more fully comprehended by reading the detailed description of the preferred embodiments enumerated below, with reference made to the accompanying drawings, wherein:

FIG. 1 (PRIOR ART) is a cross-sectional view showing a traditional nanocrystal memory;

FIG. 2 is a schematic view showing a memory unit of the present invention;

FIG. 3 is a schematic view showing a circuit of the present invention;

FIG. 4A is a schematic view showing a memory unit subjected to no applied voltage according to an embodiment of the present invention;

FIG. 4B is a schematic view showing a memory unit subjected to a high applied voltage according to an embodiment of the present invention; and

FIG. 4C is a schematic view showing a memory unit wherein a semiconductor channel subjected to an applied voltage is depleted after electric charges are stored in nanocrystals according to an embodiment of the present invention.

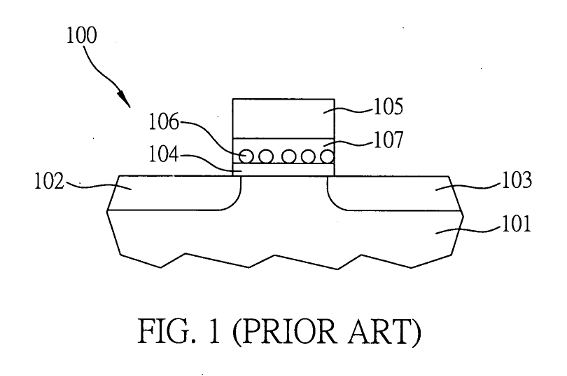

### DETAILED DESCRIPTION OF THE PREFERRED EMBODIMENTS

The resistance-change nanocrystal memory and the method for achieving memory functions in accordance with the present invention are elucidated in the following preferred embodiments and relevant drawings.

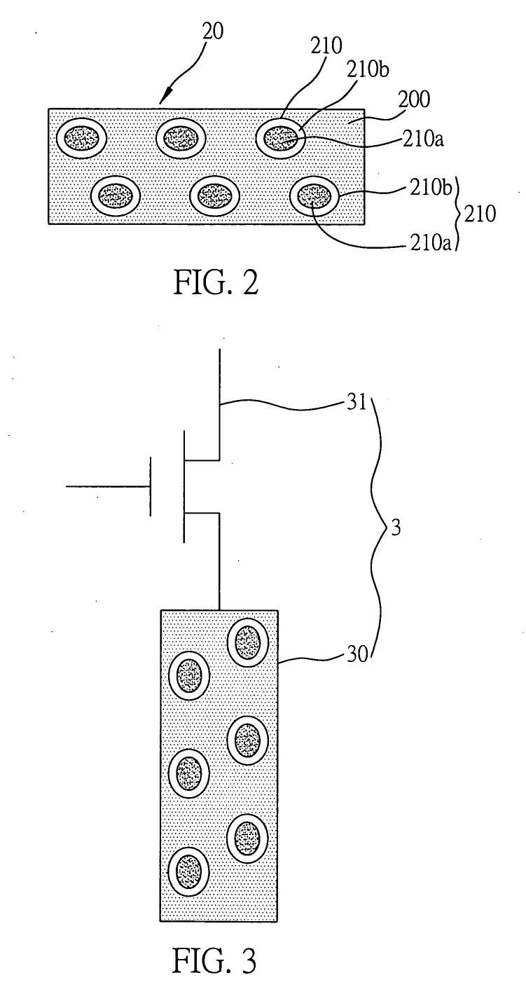

As shown in FIG. 2, a memory unit 20 of a resistance-change nanocrystal memory of the present invention includes a channel 200, and a plurality of nanocrystals 210 formed in the channel 200. The channel 200 is made of a semiconductor material which comprises a known inorganic semiconductor material and/or a known organic semiconductor material, and the inorganic semiconductor material includes, for example, doped polysilicon. Each of the nanocrystals 210 comprises an electrically conductive particle 210a and an insulating layer 210b that encloses the electrically conductive particle 210a. Each of the nanocrystals 210 is capable of storing an electric charge. Once an electric charge is stored in one of the nanocrystals 210, the resistance of the channel 200 would be directly affected by the electric charge stored in the nanocrystal 210. In other words, the electric charges stored in the nanocrystals 210 can affect the channel 200 disposed outside the nanocrystals 210 and alter the resistance of the channel 200, such that a “0” and a “1” of the memory can be read and judged effectively.

FIG. 3 is a schematic view showing the resistance-change nanocrystal memory of the present invention. The resistance-change nanocrystal memory 3 of the present invention comprises at least a memory unit 30 as described above and a transistor 31 connected in series with the memory unit 30 and configured to read the electric current passing through the memory unit 30. The transistor 31 is used for selecting a word line in the memory unit 30, and the electric current it reads is determined by the resistance of the memory unit 30. In other words, the resistance-change nanocrystal memory 3 achieves memory functions by switching on the transistor 31 to read the electric current that passes through the memory unit 30. As a result, FIG. 3 is merely an exemplary embodiment used to explain the resistance-change nanocrystal memory of the present invention; in the present invention, the component connected to the memory unit is not limited to a transistor but can actually be any component capable of measuring or reading the electric current or resistance of the memory unit effectively with a view to achieving memory functions.

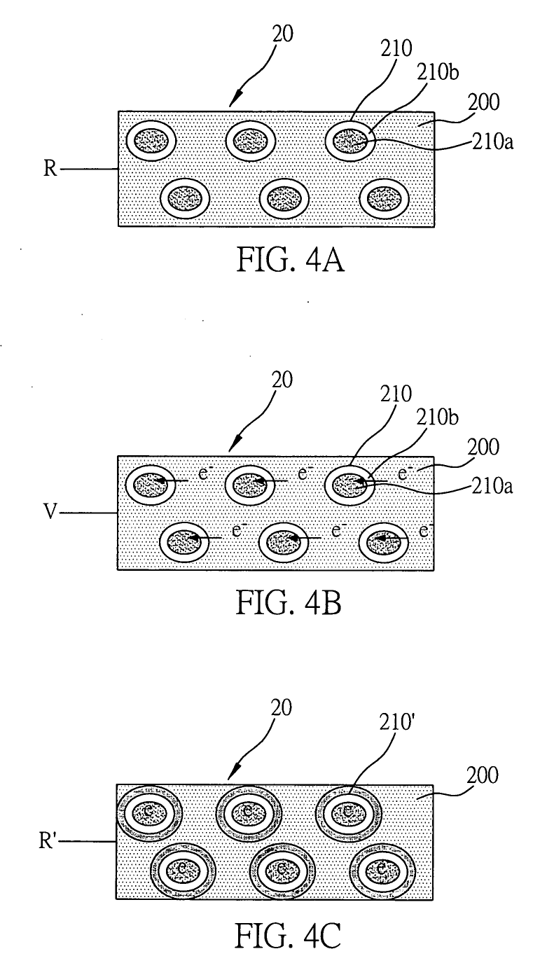

FIGS. 4A to 4C illustrate how the above resistance-change nanocrystal memory achieves memory functions; in order to simplify the illustration, the components used in measuring or reading the electric current or resistance of the memory unit are omitted in the drawings.

As shown in FIG. 4A, the memory unit 20 comprises the channel 200 and the nanocrystals 210, wherein each of the nanocrystals 210 comprises the electrically conductive particle 210a and the insulating layer 210b that encloses the electrically conductive particle 210a; each of the nanocrystals 210 is configured to store an electric charge as described above. The channel 200 is also made of a semiconductor material, which includes, for example, doped polysilicon as described above. As shown in this embodiment, where no voltage is applied to the channel 200, the resistance of the channel 200 made of a semiconductor material, which includes, for example, doped polysilicon, is denoted by R.

Moreover, as shown in FIG. 4B, under a high write-in voltage V applied to the channel 200 made of a semiconductor material, an electric charge e⁻ tunnels across the energy barrier formed by the insulating layer 210b and ends up in a nanocrystal by quantum confinement, because of a difference in electric field intensity between the channel 200 and the nanocrystal 210; in other words, the electric charge e⁻ is stored in the nanocrystal because of the high applied voltage. In an opposite situation where removal of an electric charge e⁻ from the nanocrystal requires applying a high read-out voltage so as to enable the electric charge to overcome the energy barrier again and be removed from the nanocrystal. If, however, the high read-out voltage is not applied again, the electric charge will be confined to and therefore stored in the nanocrystal.

As shown in FIG. 4C, once the electric charge e⁻ is stored in the nanocrystal, part of the channel 200 will become depleted, and at this point the nanocrystal will be denoted by 210′, which means that there is a reduction in the conductive part of the channel 200, resulting in an increased overall resistance R′ of the channel 200; at this point, the resistance R′ of the channel 200 is larger than resistance R, which is the resistance of the channel 200 under no applied voltage. For instance, given the channel 200 be n-type, part of the n-typed channel 200 is depleted under an applied voltage and therefore turned into a p-typed channel; and thus the cross-sectional area of the conductive part of the n-typed channel 200 decreases, resulting in an increased overall resistance. Therefore, if an additional transistor configured solely to read the electric current that passes through the memory unit 20 is provided, it will be possible to read and judge the “0” or “1” of the memory unit 20 in light of the level of the electric current read.

However, it should be noted that, in a situation where an additional transistor for reading the electric current of the memory unit 20 is provided, a low voltage is selectively applied with a view to reading the electric current of the memory unit 20 following the removal of the high write-in voltage applied to the memory unit 20 to allow electric charges to be stored in the nanocrystals; however, the low voltage applied at this point has to be lower than the high read-out voltage for removing from the nanocrystals the electric charges stored therein. In other words, the low voltage applied to the memory to allow the electric current of the memory unit 20 to be read should not be greater than the high read-out voltage applied to allow the electric charges to overcome the energy barrier and consequently be removed from the nanocrystals, so as to prevent the applied low voltage from causing unnecessary memory erasing. Therefore, electric charges will be confined to and thereby still stored in the nanocrystals, provided that the low voltage applied to the memory in order to read the electric current of the memory unit 20 remains low.

FIGS. 4A to 4C illustrate another method for achieving memory functions by the above resistance-change nanocrystal memory of the present invention. As shown in FIG. 4A, where the channel 200 is made of an organic semiconductor material, such as long-chain molecules of hydrocarbons or benzene rings, the molecules of the memory unit is already characterized by threshold conductivity before being subjected to an applied voltage, such that the resistance of the channel 200 made of an organic semiconductor material, such as long-chain molecules of hydrocarbons or benzene rings, is denoted by R, as shown in FIG. 4A.

As shown in FIG. 4B, given a high applied voltage V, electric charges appear between the molecules of the memory unit 20 due to an electric field. Upon removal of the high applied voltage from the memory unit 20, the read resistance of the memory unit does not equal the one read before the high applied voltage is applied, and thus the overall resistance of the channel 200 is denoted by R′, as shown in FIG. 4C. This is because the conductivity of the molecules of the memory unit 20 changes, depending on whether electric charges are stored in the nanocrystals or not. For example, the conductivity of a molecule varies due to the twisting of the molecule itself, structural changes, or changes in electron cloud distribution. Before a voltage is applied, a molecule is characterized by conductivity as electron clouds overlap one another, allowing its electric charges to flow. Once a voltage is applied and thus electric field is produced, the electron clouds may become discrete due to the changes in orientation or shape of molecules, thereby affecting its conductivity. As a result, according to this embodiment of the present invention, if an additional transistor for reading the content in the memory unit is provided, a “0” and a “1” of the memory can be read and judged effectively in light of the strength of the electric current read.

The preferred embodiments described above only serve the purpose of explaining the principle and effects of the present invention, and are not to be used to limit the scope of the present invention. Basing on the purpose and the scope of the present invention, the present invention encompasses various modifications and similar arrangements, and its scope should be covered by the claims listed in the following pages.

What is claimed is:

1. A memory unit of a resistance-change nanocrystal memory, the memory unit comprising:
a semiconductor material;
a channel formed in the semiconductor material; and
a plurality of nanocrystals located in the channel and configured to store electric charges so as to determine electrical properties of the channel, accessing the electric charges in the plurality of nanocrystals by voltage applied to the channel.

2. The memory unit of the resistance-change nanocrystal memory of claim 1, wherein the semiconductor material is at least one of an inorganic semiconductor material and an organic semiconductor material.

3. The memory unit of the resistance-change nanocrystal memory of claim 1, wherein the semiconductor material includes doped polysilicon.

4. The memory unit of the resistance-change nanocrystal memory of claim 1, wherein each of the nanocrystals comprises an electrically conductive particle and an insulating layer enclosing the electrically conductive particle.

5. A resistance-change nanocrystal memory, comprising:
at least one memory unit, comprising:
a semiconductor material;
a channel formed in the semiconductor material; and
a plurality of nanocrystals located in the channel and configured to store electric charges, with a view to determining electrical properties of the channel and accessing the electric charges in the plurality of nanocrystals by voltage applied to the channel; and
a reading component for reading an electric current passing through the memory unit.

6. The resistance-change nanocrystal memory of claim 5, wherein the semiconductor material is at least one of an inorganic semiconductor material and an organic semiconductor material.

7. The resistance-change nanocrystal memory of claim 5, wherein the semiconductor material includes doped polysilicon.

8. The resistance-change nanocrystal memory of claim 5, wherein each of the nanocrystals comprises an electrically conductive particle and an insulating layer enclosing the electrically conductive particle.

9. The resistance-change nanocrystal memory of claim 5, wherein the reading component for reading the electric current is a transistor.

10. A reading method for reading a resistance value of the resistance-change nanocrystal memory of claim 5 and thereby achieving memory functions, the reading method comprising the steps of:
reading the resistance value of the resistance-change nanocrystal memory before applying a specific voltage;
applying the specific voltage to the memory;
removing the specific voltage from the memory; and
reading the resistance value of the memory after removal of the specific voltage.

11. The reading method of claim 10, wherein the specific voltage applied is sufficient to store electric charges in nanocrystals in the resistance-change nanocrystal memory.

12. The reading method of claim 10, wherein after removal of the specific voltage, a voltage used in reading the resistance value of the memory is less than the specific voltage.

13. The reading method of claim 12, wherein the voltage used in reading the resistance value of the memory is less than a voltage for memory erasing.
